(19) United States
(12) Patent Application Publication
(10) Pub. No.: US 2025/0294822 A1
(43) Pub. Date: Sep. 18, 2025

(54) SEMICONDUCTOR DEVICE

(71) Applicant: FUJI ELECTRIC CO., LTD., Kawasaki-shi (JP)

(72) Inventors: Shin MIYAMOTO, Matsumoto-city (JP); Yuichi HASHIZUME, Matsumoto-city (JP)

(73) Assignee: FUJI ELECTRIC CO., LTD., Kawasaki-shi (JP)

(21) Appl. No.: 19/039,925

(22) Filed: Jan. 29, 2025

(30) Foreign Application Priority Data
Mar. 14, 2024 (JP) 2024-040573

(51) Int. Cl. H10D 62/10; H10D 8/60; H10D 62/832; H10D 62/85; H10D 64/62; H10D 64/64

(52) U.S. Cl. CPC H10D 62/103; H10D 8/60; H10D 62/8325; H10D 62/8503; H10D 64/62; H10D 64/64

(57) ABSTRACT

A semiconductor device has: a semiconductor substrate of a first conductivity type; a first region of the first conductivity type, provided in the semiconductor substrate and exposed at a main surface of the semiconductor substrate; a plurality of second regions of a second conductivity type, in contact with the first region, selectively provided in surface regions of the first region; a plurality of silicide films respectively in ohmic contact with the plurality of second regions; and an electrode in contact with the plurality of silicide films and forming a plurality of Schottky junctions with the first region. The plurality of silicide films have contact regions that are in contact with the first region.

### CROSS REFERENCE TO RELATED APPLICATIONS

This application is based upon and claims the benefit of priority of the prior Japanese Patent Application No. 2024-040573, filed on Mar. 14, 2024, the entire contents of which are incorporated herein by reference.

### BACKGROUND OF THE INVENTION

### 1. Field of the Invention

Embodiments of the disclosure relate to a semiconductor device.

### 2. Description of the Related Art

Conventionally, a semiconductor device that reduces reverse leakage current and threshold voltage by providing an anode electrode so as to be in contact with a surface of a SiC epitaxial layer and form a Schottky junction has been proposed (for example, refer to Japanese Laid-Open Patent Publication No. 2013-30618). Further, it has been proposed that by implanting phosphorus (P) ions into an area to make the area an amorphous layer and then by performing a heat treatment, the amorphous layer is recrystallized into a cubic single crystal n-type silicon carbide, whereby an ohmic contact between an electrode and silicon carbide is realized (for example, refer to Japanese Laid-Open Patent Publication No. 2009-49198).

### SUMMARY OF THE INVENTION

According to an embodiment of the present disclosure, a semiconductor device includes: a semiconductor substrate of a first conductivity type, the semiconductor substrate having a first main surface and a second main surface opposite to each other; a first region of the first conductivity type, provided in the semiconductor substrate, the first region being exposed at the first main surface of the semiconductor substrate; a plurality of second regions of a second conductivity type, selectively provided in the first region at a surface of the first region, and being in contact with the first region; a plurality of silicide films respectively in ohmic contact with the plurality of second regions; and an electrode in contact with the plurality of silicide films and forming a plurality of Schottky junctions with the first region. At least one of the plurality of silicide films has a contact region that is in contact with the first region.

Objects, features, and advantages of the present disclosure are specifically set forth in or will become apparent from the following detailed description of the invention when read in conjunction with the accompanying drawings.

### BRIEF DESCRIPTION OF THE DRAWINGS

FIG. 1 is a cross-sectional view depicting a structure of a semiconductor device according to an embodiment.

FIG. 2 is a perspective view depicting the structure of a region S of the semiconductor device according to the embodiment depicted in FIG. 1.

FIG. 3 is a cross-sectional view depicting a gap width of p⁺-type regions of an active region and operation during reverse voltage application.

FIG. 4 is a cross-sectional view depicting the gap width of the p⁺-type regions of the active region and operation during reverse voltage application.

FIG. 5 is a graph depicting a relationship between the gap width of the p⁺-type regions of the active region and conforming rate.

FIG. 6A is a plan view depicting the structure of the semiconductor device according to the embodiment.

FIG. 6B is a plan view depicting another example of the structure of the semiconductor device according to the embodiment.

FIG. 7 is a plan view of another example of the structure of the semiconductor device according to the embodiment.

FIG. 8 is a plan view of another example of the structure of the semiconductor device according to the embodiment.

FIG. 9 is a cross-sectional view depicting a structure of a conventional silicon carbide semiconductor device.

FIG. 10 is a perspective view depicting a structure of a region S depicted in FIG. 9 with the ohmic metal of the conventional semiconductor device.

### DETAILED DESCRIPTION OF THE INVENTION

First, problems associated with the conventional techniques are discussed. When a diode chip employing an ohmic metal is manufactured, particles or other factors may adversely affect formation of a p-type semiconductor region directly beneath the ohmic metal, whereby a defective chip may be formed in which a semiconductor material and the ohmic metal are in direct contact with each other and a large leakage current flows when reverse voltage is applied.

An outline of an embodiment of the present disclosure is described. A semiconductor device according to the present disclosure solving the problems described above has the following features. The semiconductor device has a semiconductor substrate of a first conductivity type; a first region of the first conductivity type, provided in the semiconductor substrate and exposed at a first main surface of the semiconductor substrate; a plurality of second regions of a second conductivity type, selectively provided in contact with the first region, in surface regions of the first region; a plurality of silicide films in ohmic contact with the plurality of second regions; and an electrode in contact with the plurality of silicide films and forming a plurality of Schottky junctions with the first region. The plurality of silicide films have contact regions that are in contact with the first region.

According to the disclosure described above, the plurality of second regions (the p⁺-type regions) are provided with gaps. In the gaps, the contact regions between the first region (n⁻-type drift region) and the silicide films (ohmic metal) are free of Schottky barriers and thus, the threshold value of the applied forward voltage (VF) is eliminated and operation from a low VF region becomes possible. Furthermore, a depletion layer blocks leakage current from the contact regions between the first region (n⁻-type drift region) and the silicide films and defective chips do not occur.

Further, in the semiconductor device according to the present disclosure, in the disclosure above, in a plan view, the contact regions are within 0.5 μm from the plurality of second regions.

Further, in the semiconductor device according to the present disclosure, in the disclosure above, the contact regions are sandwiched by the plurality of second regions.

Further, in the semiconductor device according to the present disclosure, in the disclosure above, an interval between the plurality of second regions sandwiching the contact region is 1 μm or less.

Further, in the semiconductor device according to the present disclosure, in the disclosure above, the plurality of silicide films contain Ni, Ti, or Al.

Further, in the semiconductor device according to the present disclosure, in the disclosure above, the plurality of second regions and the contact regions are provided alternating with each other, forming a stripe-like shape in a plan view.

Further, in the semiconductor device according to the present disclosure, in the disclosure above, an interval between the stripe-like shapes of the plurality of second regions is within a range of 1.0 μm to 5.0 μm.

Further, in the semiconductor device according to the present disclosure, in the disclosure above, the contact regions contain a 3C-SiC structure.

Further, the semiconductor device according to the present disclosure, in the disclosure above, has a back electrode at a back surface of the semiconductor substrate.

Further, in the semiconductor device according to the present disclosure, in the disclosure above, the semiconductor substrate contains SiC or GaN.

The findings underlying the present disclosure are discussed. First, problems associated with conventional semiconductor devices are discussed. In recent years, silicon carbide (SiC) semiconductors have gained attention as semiconductor materials enabling fabrication (manufacture) of semiconductor devices (hereinafter, silicon carbide semiconductor devices) that exceed limits of semiconductor devices that employ a silicon (Si) semiconductor. In particular, silicon carbide semiconductors have advantages of a higher dielectric breakdown field strength and a higher thermal conductivity than silicon semiconductors and thus, are expected to be applied to high-voltage (for example, 1200 V or higher) semiconductor devices.

In an instance in which a silicon carbide semiconductor device is a diode (hereinafter, silicon carbide diode), design specifications for an n⁻-type epitaxial layer may be set for a relatively thin thickness and high dopant concentration and therefore, silicon carbide diodes of a class of about 3000V generally have a Schottky barrier diode (SBD) structure.

Normally, in a SBD structure, electric field is high at a junction interface between a semiconductor substrate and a front electrode and a problem arises in that during application of reverse voltage, increases in reverse leakage current caused by electrons tunneling through a Schottky barrier occur or increases in reverse leakage current caused by surface defects specific to silicon carbide occur. Thus, silicon carbide diodes that employ a junction barrier Schottky (JBS) structure in which Schottky junctions and pn junctions are present in the semiconductor substrate, at or near a front surface of the semiconductor substrate, have been proposed.

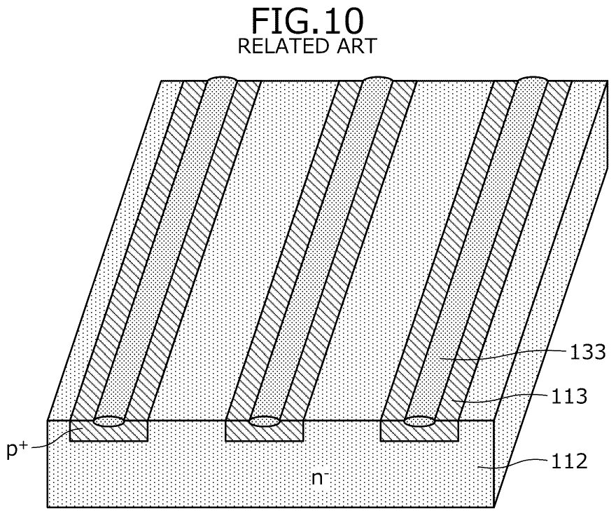

As for a structure of a conventional silicon carbide diode, a structure of a silicon carbide diode employing a JBS structure is described. FIG. 9 is a cross-sectional view depicting a structure of a conventional silicon carbide semiconductor device.

A conventional silicon carbide semiconductor device 140 depicted in FIG. 9 is a vertical silicon carbide diode having a JBS structure in which both a SBD structure constituted by Schottky junctions between an n⁻-type drift region 112 and a titanium film 131 constituting a front electrode 114, and pn junctions between p⁺-type regions 113 and the n⁻-type drift region 112 are present in a semiconductor substrate 130, at or near a front surface of the semiconductor substrate 130 in an active region 110.

The Schottky junctions of the conventional silicon carbide semiconductor device 140 are formed by portions of the n⁻-type drift region 112 exposed at the front surface of the semiconductor substrate 130 and the front electrode 114, which is constituted by the titanium film 131 and an aluminum alloy film 132 provided on the front surface of the semiconductor substrate 130. The semiconductor substrate 130 is an epitaxial substrate in which an n⁻-type epitaxial layer constituting the n-type drift region 112 is stacked on a front surface of an n⁺-type starting substrate 111, which contains silicon carbide. The n⁺-type starting substrate 111 constitutes an n⁺-type cathode region. A back electrode 119 is provided in an entire area of a back surface of the semiconductor substrate 130 and is electrically connected to the n⁺-type starting substrate 111. Reference numerals 115, 120, 120a, 124, 121, 122, 123 are, respectively, a field oxide film, an edge termination region, a connection region of the edge termination region, a field limiting ring (FLR), a p⁻-type region and a p⁻⁻-type region configuring a JTE structure, and an n⁺-type channel stopper region.

In the semiconductor substrate 130, at the front surface thereof, the p⁺-type regions 113 are selectively provided in the active region 110. Between the p⁺-type regions 113 that are adjacent to each other, portions of the n⁻-type drift region 112 are exposed at the front surface of the semiconductor substrate 130. At the front surface of the semiconductor substrate 130, pn junctions between the p³⁰ -type regions 113 and the n⁻-type drift region 112 are formed. The portions of the n⁻-type drift region 112 between the p⁺-type regions 113 that are adjacent to each other form the Schottky junctions with the titanium film 131, which is a lowermost layer of the front electrode 114 provided on the front surface of the semiconductor substrate 130.

Further, to reduce contact resistance of the p⁺-type regions 113 and the titanium film 131, which is a Schottky metal, diodes are also present in which an ohmic metal is disposed on the p⁺-type regions 113. FIG. 10 is a perspective view depicting a structure of a region S depicted in FIG. 9 with the ohmic metal of the conventional semiconductor device. In FIG. 10, nickel silicide films 133 are disposed as the ohmic metal. The nickel silicide films 133 are provided on the p⁺-type regions 113 as a lowermost layer of the front electrode 114. As depicted in FIG. 10, in the active region 110, each of the p⁺-type regions 113 and the nickel silicide films 133 is provided in a stripe-like shape. Ends of the p⁺-type regions 113 are connected to the FLR 124 and ends of the nickel silicide films 133 of the active region 110 are connected to the nickel silicide film 133 on the FLR 124.

With the described structure, when rated current flows in a forward direction, current flows in Schottky regions of the n⁻-type drift region 112 other than the p⁺-type regions 113. Furthermore, in an instance in which surge current such as lightening flows, the current cannot be passed through only the Schottky regions and thus, the p⁺-type regions 113 operate bipolarly, whereby current flows. Further, the nickel silicide films 133, which constitute ohmic regions, are provided on the p⁺-type regions 113, whereby bipolar operation is facilitated as compared a striped structure of only the p⁺-type regions 113.

However, when a diode chip that employs an ohmic metal in the active region 110 is manufactured, formation of the p⁺-type regions 113 directly beneath the ohmic metal may be adversely affected by factors such as particles. In this instance, the p⁺-type regions 113 and the ohmic metal (the nickel silicide films 133) are in direct contact and thus, a problem arises in that a defective chip is formed in which a large leakage current flows when reverse voltage is applied.

Embodiments of a semiconductor device according to the present invention are described in detail with reference to the accompanying drawings. In the present description and accompanying drawings, layers and regions prefixed with n or p mean that majority carriers are electrons or holes. Additionally, + or − appended to n or p means that the dopant concentration is higher or lower, respectively, than layers and regions without + or −. In the description of the embodiments below and the accompanying drawings, main portions that are identical will be given the same reference numerals and are not repeatedly described. Further, with consideration of variation in manufacturing, description indicating the same or equal may be within 5%.

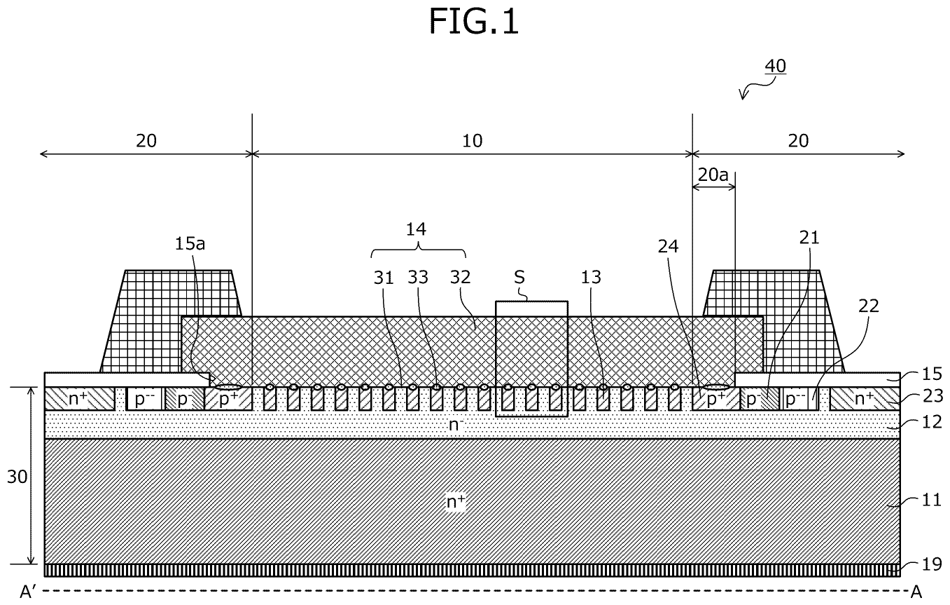

A semiconductor device according to an embodiment solving the above problems is described. A semiconductor device according to the present disclosure is formed using a wide band gap semiconductor. A structure of a silicon carbide semiconductor device is described as the semiconductor device according to the embodiment. In the semiconductor device according to the embodiment, another wide band gap semiconductor such as gallium nitride (GaN) may be used. FIG. 1 is a cross-sectional view depicting the structure of the semiconductor device according to the embodiment.

A silicon carbide semiconductor device 40 according to the embodiment depicted in FIG. 1 is a silicon carbide diode with a JBS structure in which, in a semiconductor substrate 30, at a front surface (first main surface) thereof, a SBD structure constituted by Schottky junctions between a front electrode (first electrode) 14 and an n⁻-type drift region (first region of a first conductivity type) 12, and pn diodes formed by pn junctions between p⁺-type regions (plurality of second regions of a second conductivity type) 13 and the n⁻-type drift region 12 are present in an active region 10.

The n⁻-type drift region 12 and the p⁺-type regions 13 are arranged substantially evenly in a substantially uniform pattern at the front surface of the semiconductor substrate 30, in the active region 10, in a plan view of the silicon carbide semiconductor device 40. In a plan view of the silicon carbide semiconductor device 40, portions of the n⁻-type drift region 12 and the p⁺-type regions 13, for example, are disposed linearly forming a stripe-like pattern extending in a same longitudinal direction that is parallel to the front surface of the semiconductor substrate 30, the portions of the n⁻-type drift region 12 and the p⁺-type regions 13 are in contact with each other, repeatedly alternating with each other in a lateral direction that is orthogonal to the longitudinal direction and parallel to the front surface of the semiconductor substrate 30. Between the p⁺-type regions 13 that are adjacent to each other, portions of the n⁻-type drift region 12 are exposed at the front surface of the semiconductor substrate 30.

The active region 10 is a region through which current flows when the silicon carbide diode is in an on-state. The active region 10, for example, has a substantially rectangular shape in a plan view and is disposed in substantially a center of the semiconductor substrate 30. An edge termination region 20 is a region between the active region 10 and an end of the semiconductor substrate 30 and surrounds a periphery of the active region 10. The edge termination region 20 is a region of the n⁻-type drift region 12, relaxing electric field of a front side of the semiconductor substrate 30 and sustaining a breakdown voltage. The breakdown voltage is a voltage limit at which no malfunction or destruction of the device occurs.

In the edge termination region 20, a voltage withstanding structure such as a junction termination extension (JTE) structure is disposed. The JTE structure is a voltage withstanding structure constituted by multiple p-type regions (in FIG. 1, a p⁻-type region 21 and a p⁻⁻-type region 22 are depicted) of differing dopant concentrations arranged in descending order of dopant concentration in a direction from the center of the semiconductor substrate 30) to the end of semiconductor substrate 30 and having, in a plan view, a substantially rectangular shape surrounding the periphery of the active region 10.

Further, a field limiting ring (FLR) 24 is disposed in the edge termination region 2. The FLR 24 is a p⁺-type region that surrounds the periphery of the active region 10 in a substantially rectangular shape in a plan view, extending toward the end of the semiconductor substrate 30 from a connection region 20a of the edge termination region 20 and being in contact with the p⁻-type region 21. The FLR 24 may be in contact with the p⁺-type regions 13 in the longitudinal direction in which the p⁺-type regions 13 are arranged linearly in a stripe-like shape (row).

The connection region 20a of the edge termination region 20 is a region between the active region 10 and a later-described field oxide film 15, the connection region 20a surrounds the periphery of the active region 10 and connects the active region 10 and a voltage withstanding structure portion of the edge termination region 20. The voltage withstanding structure portion of the edge termination region 20 is a portion of the edge termination region 20, from an end of the field oxide film 15 (the end facing the center of the semiconductor substrate 30) to the end of the semiconductor substrate 30 (chip end) in which predetermined voltage withstanding structures such as the JTE structure including the p⁻-type region 21, the p⁻⁻-type region 22, etc., and an n⁺-type channel stopper region 23 are disposed.

The front electrode 14 is provided on the front surface of the semiconductor substrate 30, in the active region 10. The front electrode 14 is in contact with the n⁻-type drift region 12 and the p⁺-type regions 13 and is electrically connected to the n⁻-type drift region 12 and the p⁺-type regions 13.

On the front surface of the semiconductor substrate 30, a passivation film (not depicted) is provided. The passivation film functions as a protective film that protects device structures of the front side of the semiconductor substrate 30 and the front electrode 14.

An opening that exposes a portion of the front electrode 14 is provided in the passivation film. The portion of the front electrode 14 exposed in the opening of the passivation film functions as a bonding pad. The bonding pad is disposed, for example, in the center of the semiconductor substrate 30. An aluminum (Al) wire, which is a most common wiring connection when current is to be supplied to the bonding pad, is bonded to the bonding pad.

Next, a cross-section of the structure of the silicon carbide semiconductor device 40 according to the embodiment is described. As described above, the silicon carbide semiconductor device 40 according to the embodiment includes a JBS structure having pn diodes and a SBD structure of silicon carbide diodes in the active region 10 of the semiconductor substrate 30, which contains silicon carbide, and the silicon carbide semiconductor device 40 further includes the JTE structure, as a voltage withstanding structure, in the edge termination region 20.

The semiconductor substrate 30 is an epitaxial substrate in which an n⁻-type epitaxial layer constituting the n⁻-type drift region 12 is stacked on a front surface of an n⁺-type starting substrate 11 that contains silicon carbide. The n⁺-type starting substrate 11 constitutes an n⁺-type cathode region. The semiconductor substrate 30 has a first main surface (surface of the n⁻-type epitaxial layer constituting the n⁻-type drift region 12) as the front surface and a second main surface (back surface of the n⁺-type starting substrate 11) as a back surface.

In the semiconductor substrate 30, at the front surface thereof in the active region 10, one or more of the p⁺-type regions 13 configuring a pn diode is selectively provided. The p⁺-type regions 13 are provided between the front surface of the semiconductor substrate 30 and the n⁻-type drift region 12. The p⁺-type regions 13 are exposed at the front surface of the semiconductor substrate 30 and are in contact with the n⁻-type drift region 12.

In the semiconductor substrate 30, at the front surface thereof in the edge termination region 20, the FLR 24, one or more p-type regions (herein, two: the p⁻-type region 21 and the p⁻⁻-type region 22) configuring the JTE structure, and the n⁺-type channel stopper region 23 are each selectively provided. The FLR 24 is provided in an entire area of the connection region 20a of the edge termination region 20; the FLR 24 extends toward the end of the semiconductor substrate 30 from the connection region 20a and is in contact with the p⁻-type region 21. An end of the FLR 24 facing the center of the semiconductor substrate 30 borders the active region 10.

The p⁻-type region 21 is apart from the connection region 20a of the edge termination region 20, closer to the end of the semiconductor substrate 30 than is the FLR 24 and is adjacent to the FLR 24. The p⁻⁻-type region 22 is closer to the end of the semiconductor substrate 30 than is the p⁻-type region 21 and is adjacent to the p⁻-type region 21. The n⁺-type channel stopper region 23 is apart from the p⁻⁻-type region 22 and closer to the end of the semiconductor substrate 30 than is the p⁻⁻-type region 22. The n⁺-type channel stopper region 23 is exposed at the end of the semiconductor substrate 30 (chip end).

The FLR 24, the p⁻-type region 21, the p⁻⁻-type region 22, and the n⁺-type channel stopper region 23 are provided between the front surface of the semiconductor substrate 30 and the n⁻-type drift region 12. The FLR 24, the p⁻-type region 21, the p⁻⁻-type region 22, and the n⁺-type channel stopper region 23 are exposed at the front surface of the semiconductor substrate 30 and are in contact with the n⁻-type drift region 12. Depths of the FLR 24, the p⁻-type region 21, the p⁻⁻-type region 22, and the n⁺-type channel stopper region 23 are, for example, a same depth as a depth of the p⁺-type regions 13.

The field oxide film 15 covers the front surface of the semiconductor substrate 30. The field oxide film 15 may be a stacked film in which, for example, a thermal oxide film and a deposited oxide film are sequentially stacked. The thermal oxide film may improve adhesion between the semiconductor substrate 30 and the field oxide film 15. The field oxide film 15 includes a deposited oxide film, whereby the field oxide film 15 may be formed in a shorter time as compared to an instance in which the entire field oxide film 15 is a thermal oxide film.

The field oxide film 15 has a contact hole 15a that exposes nearly an entire area of the front surface of the semiconductor substrate 30 in the active region 10. A sidewall (side surface of the field oxide film 15 facing the center of the semiconductor substrate 30) of the contact hole 15a of the field oxide film 15 is, for example, substantially orthogonal to the front surface of the semiconductor substrate 30. The contact hole 15a of the field oxide film 15 is in an entire area of the active region 10 and the connection region 20a of the edge termination region 20.

The p⁺-type regions 13 and the n⁻-type drift region 12 in the active region 10 are exposed by the contact hole 15a of the field oxide film 15. The FLR 24 in the connection region 20a of the edge termination region 20 is also exposed. In the contact hole 15a of the field oxide film 15, on the front surface of the semiconductor substrate 30, the front electrode 14, which functions as an anode electrode, is provided along the front surface of the semiconductor substrate 30.

The front electrode 14 has a stacked structure in which a titanium film 31 and an aluminum alloy film (metal electrode film containing aluminum) 32 are sequentially stacked. In addition, the front electrode 14 has, as a lowermost layer, nickel silicide (NiSi) films 33 that are selectively provided between the front surface of the semiconductor substrate 30 and the titanium film 31. The nickel silicide films 33 contain aluminum. The nickel silicide films 33 may contain carbon (C). The front electrode 14 may extend on the field oxide film 15, in a direction toward the end of the semiconductor substrate 30. Other than the nickel silicide (NiSi) films 33, the ohmic metal may be a titanium silicide (TiSi) film, an aluminum silicide (AlSi) film, or a combination of these films.

The titanium film 31 is provided on an entire portion of the front surface of the semiconductor substrate 30 in the contact hole 15a and is in contact with the n⁻-type drift region 12. Portions of the titanium film 31 are bonded to the n⁻-type drift region 12 and constitute Schottky electrodes forming Schottky junctions with the n⁻-type drift region 12. The titanium film 31 extends on the field oxide film 15 in a direction toward the end of the semiconductor substrate 30 and, for example, in a depth direction, may terminate at a position facing the FLR 24.

The aluminum alloy film 32 covers an entire area of the surface of the titanium film 31, is electrically connected to the titanium film 31, and is electrically connected to the nickel silicide films 33 via the titanium film 31. The aluminum alloy film 32 extends on the field oxide film 15, closer to the end of the semiconductor substrate 30 than is the titanium film 31 and, for example, in the depth direction, may terminate at a position facing the p⁻⁻-type region 22. The aluminum alloy film 32 is, for example, an aluminum silicon (AlSi) film. Instead of the aluminum alloy film 32, an aluminum film or an aluminum-silicon-copper (AlSiCu) film may be provided.

The nickel silicide films 33 are selectively provided between the titanium film 31 and the p⁺-type regions 13. The nickel silicide films 33 are ohmic electrodes in ohmic contact with the titanium film 31 and the p⁺-type regions 13. As described, the nickel silicide films 33 (ohmic metal) are disposed on the p⁺-type regions 13 of the active region 10, whereby contact resistance between the titanium film 31 (Schottky metal) and the p⁺-type regions 13 decreases and thus, the amount of heat generated when a large current flows through the active region 10 is reduced and chip capability (IFSM capability) with respect to heat generation when a large current flows is increased.

The nickel silicide films 33 are provided in the semiconductor substrate 30, at the front surface thereof, are in contact with the p⁺-type regions 13 in the depth direction, and may protrude from the front surface of the semiconductor substrate 30 in a direction away from the front surface of the semiconductor substrate 30.

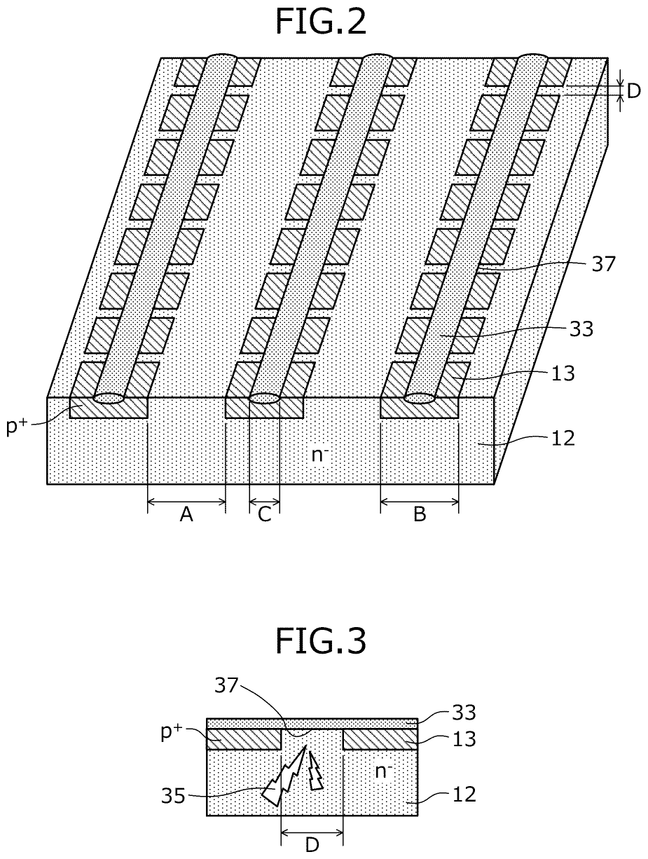

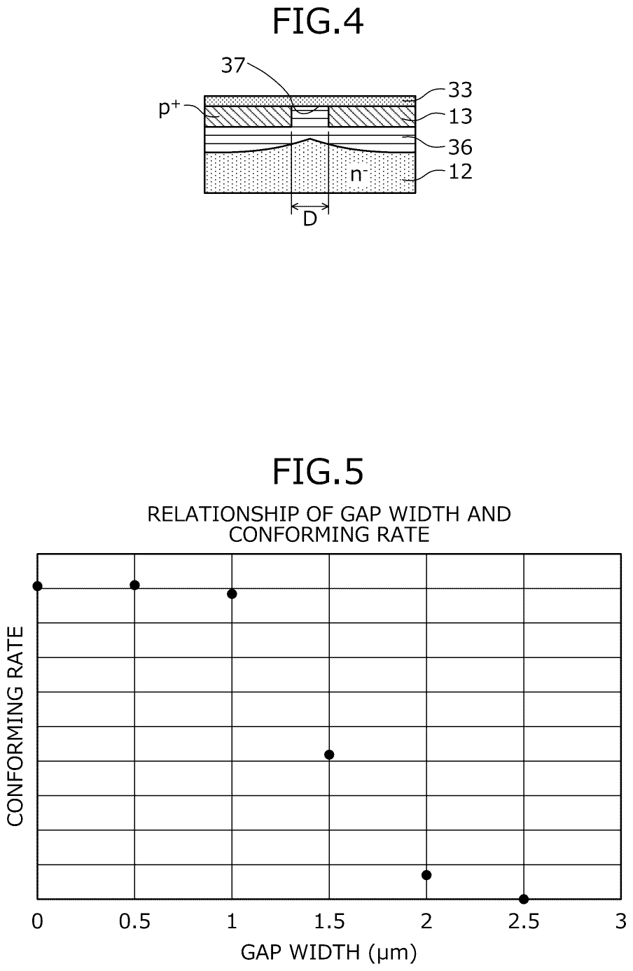

FIG. 2 is a perspective view depicting the structure of a region S of the semiconductor device according to the embodiment depicted in FIG. 1. As depicted in FIG. 2, in the embodiment, the p⁺-type regions 13 of the active region 10 are disposed linearly in rows forming the stripe-like pattern with the n⁻-type drift region 12; in each of the rows, the p⁺-type regions 13 of the active region 10 are disposed adjacently with gaps therebetween, each of the gaps having a width (gap width D) of, for example, 1.0 μm or less. In the gaps, contact regions 37 (refer to FIGS. 3 and 4) where the n⁻-type drift region 12 and the nickel silicide film 33 (ohmic metal) are in contact with each other are formed, whereby the p⁺-type regions 13 and the contact regions 37 are provided alternating with each other. The contact regions are free of a Schottky barrier and thus, a threshold value of the applied forward voltage (VF) is eliminated and operation from a low VF region becomes possible.

FIGS. 3 and 4 are cross-sectional views depicting the gap width of the p⁺-type regions of the active region and operation during reverse voltage application. As depicted in FIGS. 3 and 4, the contact regions 37 between the n⁻-type drift region 12 and the nickel silicide films 33 are sandwiched by the p⁺-type regions 13. FIG. 3 depicts an instance in which the gap width D of the p⁺-type regions 13 is the gap width D>2 μm and when the gaps are between the p⁺-type regions 13, which are directly beneath the nickel silicide films 33, a leakage current 35 flows from the contact regions 37, resulting in a defective chip that does not operate as a diode. On the other hand, FIG. 4 depicts an instance in which the gap width D of the p⁺-type regions 13 is the gap width D≤1 μm and in this instance, a depletion layer 36 that spreads from pn junctions on both sides completely covers the contact regions 37 and thus, leakage current from the contact regions 37 is blocked by the depletion layer 36. Thus, for the contact regions 37 where the n⁻-type drift region 12 and the nickel silicide films 33 are in contact with each other, preferably, the gap width D between any adjacent two of the p⁺-type regions 13 may be within 1 μm in a plan view. In other words, in a plan view, the contact regions 37 may be, preferably, within 0.5 μm from the p⁺-type regions 13.

FIG. 5 is a graph depicting a relationship between the gap width of the p⁺-type regions of the active region and conforming rate. In FIG. 5, a horizontal axis indicates the gap width D in units of μm. A vertical axis indicates the conforming rate. FIG. 5 shows results obtained for electrical characteristics by wafer acceptance test (WAT) measurement when the p⁺-type regions 13, which are directly beneath the nickel silicide films 33, are created having gaps therebetween with the gap width D set as a condition. An experiment was carried out with a SBD under conditions including: a polytype 4H-n-type, a dopant of the n-type drift region 12 being nitrogen (N), the dopant concentration being 8.80×10¹⁵±30% cm⁻³, a thickness being 10±10% μm, a Schottky metal being a titanium film, and a dopant of the p⁺-type regions 13 being aluminum (Al).

As depicted in FIG. 5, when the gap width D is greater than 1.0 μm, the leakage current increases and the conforming rate decreases. Thus, in the embodiment, preferably, the gap width D may be in a range of 0.2 μm to 1.0 μm. Further, an interval A between any adjacent two of the rows of the p⁺-type regions 13 that sandwich the contact regions 37 depicted in FIG. 2, preferably, may be in a range of 1.0 μm to 5.0 μm so that the depletion layer 36 does not close between the p⁺-type regions 13. When the dopant concentration of the n⁻-type drift region 12 is low, the depletion layer 36 spreads easily and thus, the dopant concentration of the n⁻-type drift region 12, preferably, may be in a range of 1.0×10¹⁵/cm³ to 1.0×10¹⁷/cm3. Further, a width B of each of the p⁺-type regions 13 depicted in FIG. 2, preferably, may be in a range of 1.0 μm to 3.0 μm. A width C of each of the nickel silicide films 33 depicted in FIG. 2, preferably, may be in a range of 0.5 μm to 2.0 μm.

Further, instead of the nickel silicide films 33, the contact regions 37 may be fabricated by a semiconductor with a 3C-SiC structure. An ohmic contact is formed by the semiconductor with a 3C-SiC structure and the titanium film 31 or the aluminum alloy film 32 and thus, disposal of an ohmic metal is unnecessary. In this instance, the semiconductor with a 3C-SiC structure has a same structure as the structure of the nickel silicide films 33, in other words, has a stripe-like shape provided on the p⁺-type regions 13. The 3C-SiC structure may be formed by, for example, implanting ions such as argon and performing a heat treatment thereafter.

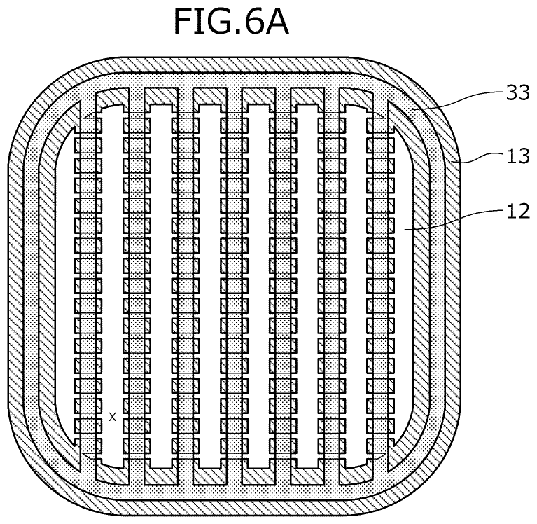

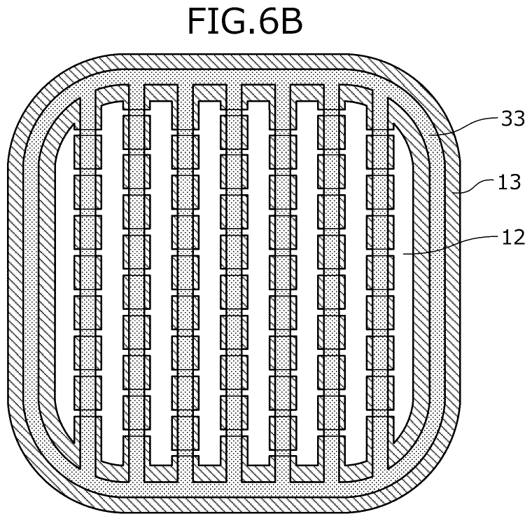

FIG. 6A is a plan view depicting the structure of the semiconductor device according to the embodiment. The structure of the semiconductor device according to the embodiment may be a structure other than the structure depicted in FIG. 6A. For example, in FIG. 6A, while the gaps between the p⁺-type regions 13 adjacent to each other in the active region 10 are at the same positions in each of the rows in the longitudinal direction of the rows, the gaps between the p⁺-type regions 13 that are adjacent to each other may be staggered (at mutually different positions) in the longitudinal direction of the rows of the p⁺-type regions 13. In an instance of the structure depicted in FIG. 6A, between the gaps of the p⁺-type regions 13 of a Schottky region (in FIG. 6A, position indicated by “x”), the depletion layer does not close easily and during application of reverse voltage, reverse current IR may increase. In an instance in which the gaps of the p⁺-type regions 13 are staggered (FIG. 6B), the depletion layer of the Schottky region is easily closed and increases in reverse current IR may be prevented.

Furthermore, the p⁺-type regions 13 and the nickel silicide films 33 may be disposed in dot-like shapes in a flat densely packed arrangement. In this instance, the dot-like shaped gaps of the p⁺-type regions 13 adjacent to each other are staggered, whereby the depletion layer of the Schottky region is easily closed and increases in reverse current IR may be prevented.

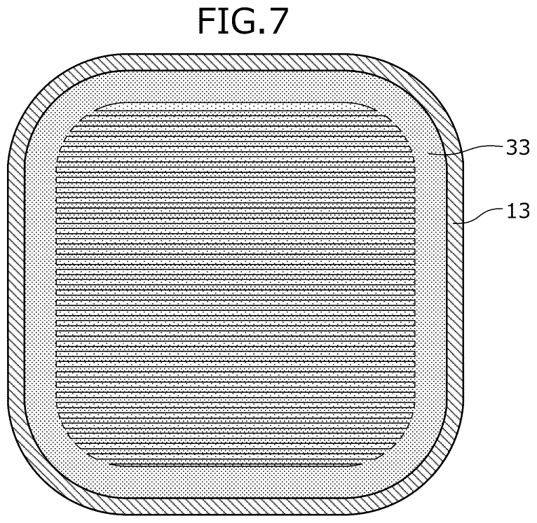

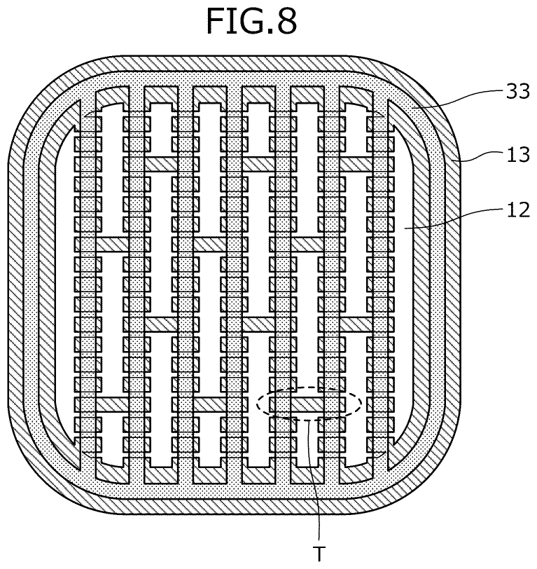

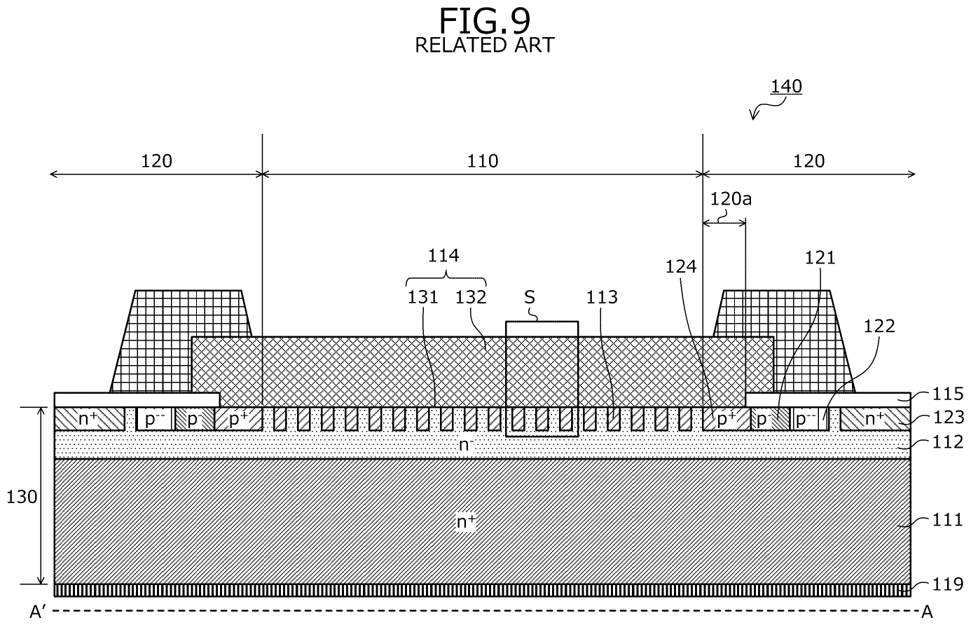

FIGS. 7 and 8 are plan views of other examples of the structure of the semiconductor device according to the embodiment. As depicted in FIG. 7, the nickel silicide film 33 is provided in an entire area of the surface of the active region 10 and all Schottky junctions are set as boundary regions, whereby a diode free of a VF threshold may also be created.

As depicted in FIG. 8, a structure is also possible in which the p⁺-type regions 13 are wider only at a few locations T at the surface of the active region 10. When IFSM or surge current flows into a circuit mounted with multiple chips in parallel, the current may concentrate in some chips where large current tends to flow, due to variations in product quality. At the surface, locations where large current easily flows (the locations T where the p⁺-type regions 13 are wide) are prepared, whereby variation between chips may be reduced during high-current operation.

The silicon carbide semiconductor device 40 according to the embodiment is described similarly to the conventional method of manufacturing. For example, the silicon carbide semiconductor device 40 is formed as follows. First, as the n⁺-type starting substrate (semiconductor wafer) 11, a 4-layer periodic hexagonal crystal (4H-SiC) substrate containing silicon carbide and doped with, for example, about 5×10¹⁸/cm³ of nitrogen (N) is prepared. Next, on the front surface of the n⁺-type starting substrate 11, the n⁻-type epitaxial layer doped with nitrogen in a range of 1.0>10¹⁵/cm³ to 1.0×10¹⁷/cm³ and constituting the n⁻-type drift region 12 is grown, thereby forming the semiconductor substrate 30.

Next, in the semiconductor substrate 30, at the front surface thereof, one or more of the p⁺-type regions 13 configuring pn diodes, and the FLR 24 are each selectively formed in the active region 10 by photolithography and ion implantation of a p-type dopant such as aluminum. In the embodiment, the p⁺-type region 13 is formed in a stripe-like shape and in the p⁺-type region 13, gaps of the gap width D are formed. Next, an entire area of the front surface of the semiconductor substrate 30 is covered and protected by, for example, a carbon (C) protective film and thereafter, the ion-implanted dopants are activated by a heat treatment.

Next, an oxide film is formed in the entire area of the front surface of the semiconductor substrate 30. Next, the oxide film is selectively removed by photolithography and etching, thereby forming an opening. Next, for example, a metal material film is formed on a portion of the front surface (surface) of the semiconductor substrate 30 in the opening of the oxide film by a sputtering method from the surface of the oxide film.

Thereafter, a first sintering is performed on the metal material film by a heat treatment, thereby generating an aluminum-nickel-silicon (Al—Ni—Si) compound in the opening of the oxide film. Next, excess metal (excess portion) on the oxide film and in the opening of the oxide film is removed.

Next, a second sintering is performed on the Al—Ni—Si compound by a heat treatment, thereby generating a nickel silicide in the Al—Ni—Si compound and the Al—Ni—Si compound is converted into the nickel silicide films 33 that are in ohmic contact with the semiconductor substrate 30.

Next, etching is performed using a resist film as a mask, thereby forming the contact hole 15a, which penetrates through the field oxide film 15 in the depth direction. Next, for example, the titanium film 31 is formed at entire surface from the surface of the field oxide film 15, to the front surface of the semiconductor substrate 30 in the contact hole 15a by a physical vapor deposition (PVD) method such as sputtering. Next, the titanium film 31 is left only in the contact hole 15a by photolithography and etching.

Next, for example, the titanium film 31 is sintered by a heat treatment for about 10 minutes, at a temperature of about 500 degrees C. Next, for example, an aluminum alloy film of a thickness of, for example, about 5 μm is formed at an entire surface, from the surface of the titanium film 31, to the surface of the field oxide film 15 by a physical vapor deposition method such as sputtering. Next, the aluminum alloy film is selectively removed by photolithography and etching and is left on the surface of the titanium film 31, as the aluminum alloy film 32 constituting the front electrode 14.

Next, for example, nickel or titanium is deposited in an entire area of a back surface (back surface of the n⁺-type starting substrate 11) of the semiconductor substrate 30 by a physical vapor deposition method such as sputtering and thereafter, a heat treatment is performed, thereby forming a back electrode 19. In the heat treatment, a rapid thermal anneal (RTA) or a laser anneal is used. Subsequently, the protective film of the front surface of the semiconductor substrate 30 is removed and thereafter, the semiconductor substrate 30 is diced (cut) into individual chips, thereby completing the silicon carbide semiconductor device 40 of the embodiment.

As described, according to the embodiment, the p⁺-type regions are provided with gaps having a width of 1.0 μm or less. In the gaps, contact regions between the n⁻-type drift region and the nickel silicide films (ohmic metal) are free of Schottky barriers and thus, the threshold value of the applied forward voltage (VF) is eliminated and operation from a low VF region becomes possible. Further, the depletion layer blocks leakage current from contact regions between the n⁻-type drift region and the nickel silicide films, and no defective chips occur.

In the foregoing, the present disclosure is not limited to the embodiments above, various modifications within a range not departing from the spirit of the disclosure are possible, and application to semiconductor devices having an ohmic electrode in ohmic contact with p-type regions disposed in a predetermined pattern is possible.

In particular, for example, the present disclosure is useful for, silicon carbide semiconductor devices having a configuration for lowering contact resistance between an ohmic electrode and a p-type region (or a p⁺-type contact region disposed between said p-type region and a main surface of a semiconductor substrate), and the present disclosure is useful for semiconductor devices having a structure in which an oxide film and an ohmic electrode are in contact with each other, and the ohmic electrode is in ohmic contact with a p-type region.

According to the disclosure, a plurality of second regions of the second conductivity type (p⁺-type regions) are provided with gaps. In the gaps, contact regions between a first region of the first conductivity type (n⁻-type drift region) and a silicide film (ohmic metal) are free of Schottky barriers and thus, the threshold value of the applied forward voltage (VF) is eliminated and operation from a low VF region becomes possible. Further, a depletion layer blocks leakage current from the contact regions between the first region of the first conductivity type (n⁻-type drift region) and the silicide films and no defective chips occur.

The semiconductor device according to the present disclosure achieves an effect in that even when a semiconductor material and an ohmic metal are in direct contact with each other, conduction from a voltage lower than a threshold voltage of a Schottky diode is possible thereby reducing forward loss during rated operation.

As described, the semiconductor device according to the present disclosure is useful for power semiconductor devices used in power converting equipment, power source devices such as those used in various types of industrial machines, and the like.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A semiconductor device, comprising:
a semiconductor substrate of a first conductivity type, the semiconductor substrate having a first main surface and a second main surface opposite to each other;
a first region of the first conductivity type, provided in the semiconductor substrate, the first region being exposed at the first main surface of the semiconductor substrate;
a plurality of second regions of a second conductivity type, selectively provided in the first region at a surface of the first region, and being in contact with the first region;
a plurality of silicide films respectively in ohmic contact with the plurality of second regions; and
an electrode in contact with the plurality of silicide films and forming a plurality of Schottky junctions with the first region, wherein
at least one of the plurality of silicide films has a contact region that is in contact with the first region.

2. The semiconductor device according to claim 1, wherein the contact region is within 0.5 μm from the plurality of second regions in a plan view of the semiconductor device.

3. The semiconductor device according to claim 1, wherein the contact region is sandwiched between adjacent two of the plurality of second regions.

4. The semiconductor device according to claim 3, wherein an interval between the adjacent two of the plurality of second regions is no more than 1 μm.

5. The semiconductor device according to claim 1, wherein each of the plurality of silicide films contains Ni, Ti, or Al.

6. The semiconductor device according to claim 1, wherein the contact region is one of a plurality of contact regions, and the plurality of contact regions and the plurality of second regions are arranged linearly, alternating with each other to form a stripe-like shape in a plan view of the semiconductor device.

7. The semiconductor device according to claim 6, wherein the plurality of contact regions and the plurality of second regions form a plurality of stripe-like shapes, an interval between any adjacent two of the plurality of stripe-like shapes being in a range of 1.0 μm to 5.0 μm.

8. The semiconductor device according to claim 1, wherein the contact region contains a 3C-SiC structure.

9. The semiconductor device according to claim 1, further comprising a back electrode at the second main surface of the semiconductor substrate.

10. The semiconductor device according to claim 1, wherein the semiconductor substrate contains SiC or GaN.
